(19) United States
(12) Patent Application Publication
(10) Pub. No.: US 2025/0183138 A1
(43) Pub. Date: Jun. 5, 2025

(54) SEMICONDUCTOR DEVICE AND A METHOD FOR MAKING A SEMICONDUCTOR DEVICE

(71) Applicant: STATS ChipPAC Pte. Ltd, Singapore (SG)

(72) Inventors: JungSub LEE, Incheon (KR); HyunYoung KIM, Seoul (KR); YoungIn CHOI, Chungcheongbuk-do (KR)

(21) Appl. No.: 18/963,799

(22) Filed: Nov. 29, 2024

(30) Foreign Application Priority Data
Nov. 30, 2023 (CN) 202311626341.5

(51) Int. Cl. H01L 23/498; H01L 21/56; H01L 25/00; H01L 25/07

(52) U.S. Cl. CPC H01L 23/49816; H01L 21/565; H01L 25/072; H01L 25/50

(57) ABSTRACT

A method for making a semiconductor device comprises: providing one or more packages, wherein each of the one or more packages includes: a first substrate comprising a first surface and a second surface, a protection tape attached onto the first surface of the first substrate, one or more electronic components mounted on the second surface of the first substrate, and one or more conductive structures mounted on the second surface of the second substrate; mounting the one or more packages onto a first surface of a second substrate, wherein the one or more conductive structures connect the first substrate and the second substrate; applying a molding material to cover the one or more electronic components and the one or more conductive structures; and removing the protection tape from each of the one or more packages.

### TECHNICAL FIELD

The present application generally relates to semiconductor technology, and more particularly, to a semiconductor device and a method for making a semiconductor device.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Also, double-sided mounting (DSM) packages are also an option to improve the integration level of semiconductor devices.

In SiP or DSM devices, some components or packages should be covered by a molding material for protection. However, conventional molding processes may cause several issues such as mold flash. If the mold flash occurs, the molding material may leak into an interface or onto a surface of the SiP and occupy certain space where it is not desired. For example, the molding material leakage may be formed on contact pads or other similar conductive patterns, preventing solder balls from being further mounted on and electrically connected to the conductive patterns.

Therefore, a need exists for further improvement of a method for forming a molding material in a semiconductor device.

### SUMMARY OF THE INVENTION

An objective of the present application is to provide a method for forming a molding material in a semiconductor device to improve an improved quality of the molding material.

According to an aspect of the present application, a method for making a semiconductor device is disclosed. The method comprises: providing one or more packages, wherein each of the one or more packages includes: a first substrate comprising a first surface and a second surface, a protection tape attached onto the first surface of the first substrate, one or more electronic components mounted on the second surface of the first substrate, and one or more conductive structures mounted on the second surface of the first substrate; mounting the one or more packages onto a first surface of a second substrate, wherein the one or more conductive structures connect the first substrate and the second substrate; applying a molding material to cover the one or more electronic components and the one or more conductive structures; and removing the protection tape from each of the one or more packages.

According to another aspect of the present application, a semiconductor device is provided, which may be formed using the method of the above aspect.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of a semiconductor device formed according to a conventional method.

FIG. 2 illustrates a flowchart of a method for making a semiconductor device according to an embodiment of the present application.

FIGS. 3A to 3H illustrate cross-sectional views showing the method of FIG. 2 for making a semiconductor device.

FIG. 4 illustrates a flowchart of a method for making a package according to an embodiment of the present application.

FIGS. 5A to 5D illustrate cross-sectional views showing the method of FIG. 4 for making a package.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for case of description to describe one element or feature's relationship to another clement(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other clement, or intervening elements may be present.

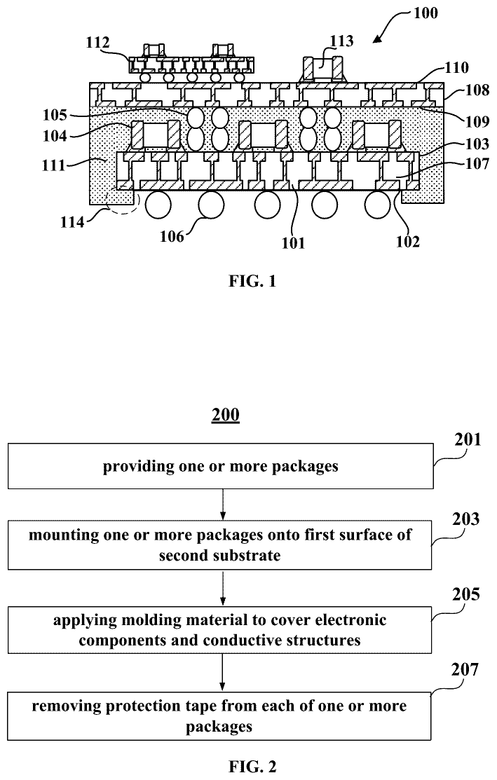

FIG. 1 illustrates a cross-sectional view of a semiconductor device 100 formed according to a conventional method.

As shown in FIG. 1, the semiconductor device 100 includes a first substrate 101 with a first surface 102 and a second surface 103 which is opposite to the first surface 102. The first substrate 101 may include a redistribution structure (RDS) having one or more dielectric layers and one or more conductive layers between and through the dielectric layers. One or more electronic components 104 and conductive structures 105 are mounted on the second surface 103 of the first substrate 101. One or more conductive structures 106 are mounted on the second surface 103 of the first substrate 101, to electrically connect the semiconductor device 100 to another external device such as a main circuit board. The conductive structures 105 and the conductive structures 106 may include solder balls and/or metal posts such as copper posts, or any other similar structures or elements that can provide functionality of electrical interconnection. The first substrate 101, the electronic components 104, the conductive structures 105 and the conductive structures 106 and a molding material 111 encapsulating these various components and structures together form a first package 107, as a part of the semiconductor device 100.

Further, the semiconductor device 100 includes a second substrate 108 with a first surface 109 and a second surface 110 which is opposite to the first surface 109. The second substrate 108 may include a redistribution structure having one or more dielectric layers and one or more conductive layers between and through the dielectric layers. The first package 107 is mounted on the first surface 109 of the second substrate 108, with the conductive structures 105 electrically connecting the first substrate 101 with the second substrate 108, so that electrical signals can be transmitted between electronic components mounted on the first substrate 101 and the second substrate 108. As can be seen, the molding material 111 is formed between the first substrate 101 and the second substrate 108, to cover the electronic components 104 and the conductive structures 105 for protection, and mechanically connecting the first substrate 101 with the second substrate 108 to enhance the integrity and stability of the semiconductor device 100.

When the conventional process is used to form the semiconductor device 100, especially when the molding material 111 is applied to cover the electronic components 104 and the conductive structures 105, a mold flash 114 may be formed on the first surface 102 of the first substrate 101 and around a periphery of the first substrate 101, which is undesired for the semiconductor device 100. The mold flash 114 may advance further along the first surface 102 and occupy certain space below some conductive patterns on the first surface 102, which are left for mounting the conductive structures 106. Thus, the conductive structures 106 cannot be well mounted on the first surface 102 in some cases and may decrease the yield of the semiconductor device 100.

To address the aforementioned problem, a method for making a semiconductor device is provided according to some embodiments of the present application. With the method, a protection tape is first attached onto the first surface of the first substrate where no molding material is desired to be formed. The protection tape can then cover the first surface and prevent the formation of the molding material thereon. After the molding material is applied to cover the electronic components and the conductive structures, the protection tape can be removed from the first surface of the first substrate, so that no mold flash may be formed on there.

Referring to FIG. 2, a flowchart of a method 200 for making a semiconductor device is illustrated according to an embodiment of the present application. As illustrated in FIG. 2, the method 200 may start with providing one or more packages in block 201. Each of the one or more packages may include a first substrate, a protection tape, one or more electronic components and one or more conductive structures. Each package may include a first substrate having a first surface and a second surface, a protection tape attached onto the first surface of the first substrate, one or more electronic components mounted on the second surface of the first substrate, and one or more conductive structures mounted on the second surface of the first substrate. In block 203, the one or more packages are mounted onto a first surface of a second substrate. Then, in block 205, a molding material is applied to cover the one or more electronic components and the one or more conductive structures. After the molding material is applied, in block 207, the protection tape is removed from each of the one or more packages.

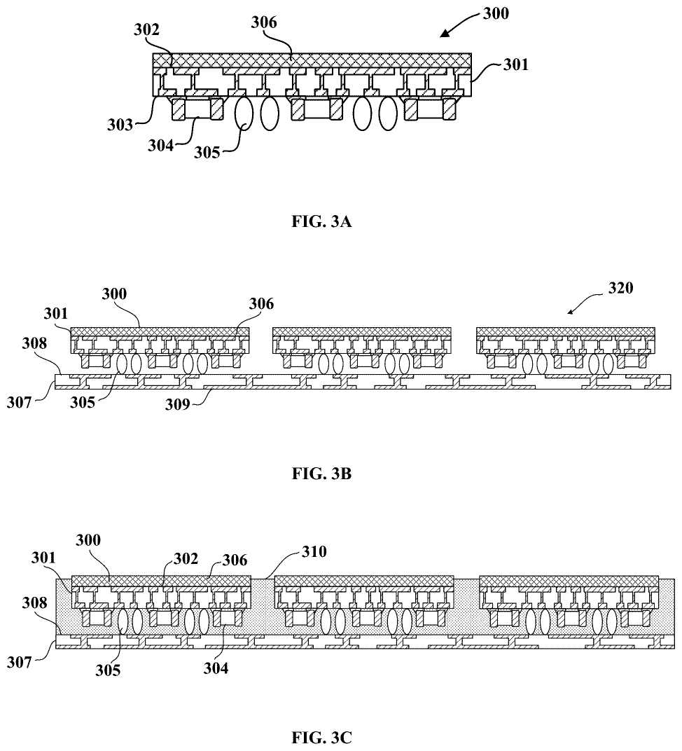

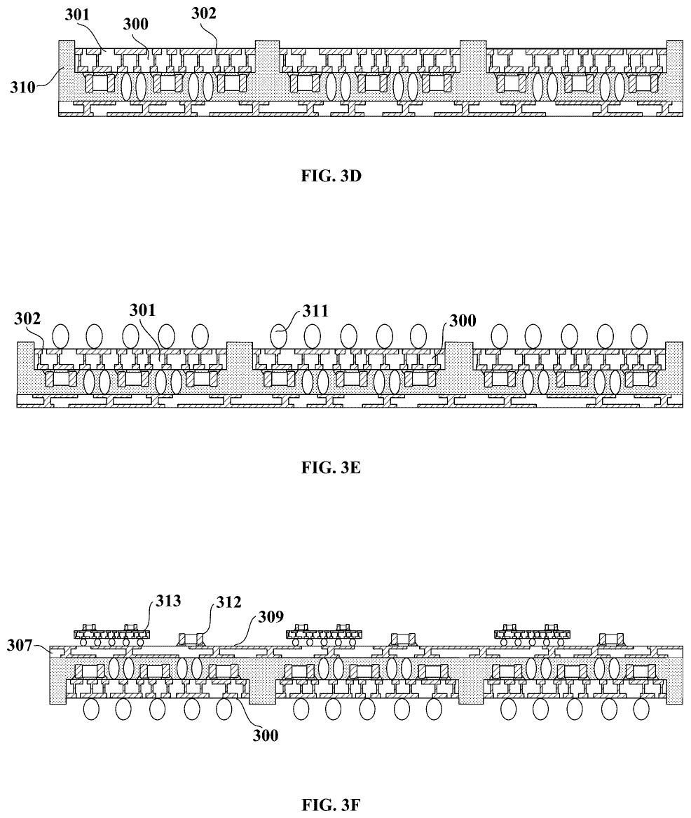

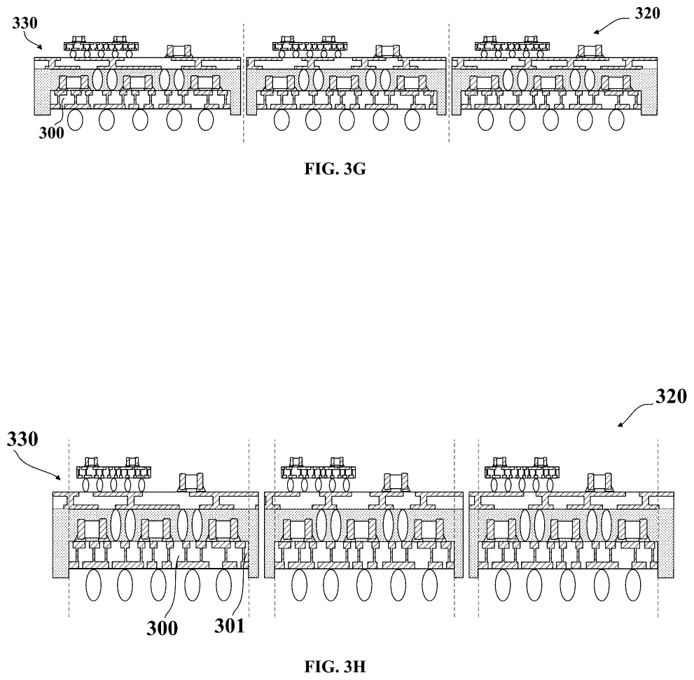

Referring to FIGS. 3A to 3H, cross-sectional views illustrating various blocks of the method for making a semiconductor device are illustrated. In the following, the method will be described with reference to FIG. 2 and FIGS. 3A to 3H in more details.

In particular, the process starts with providing one or more packages, and one of the packages 300 is illustrated in FIG. 3A as an example. It can be appreciated that the other packages may have the same structure or have a different structure. The package 300 includes a first substrate 301 which can be a laminate interposer, PCB, wafer-form, strip interposer, leadframe, or any other suitable substrate. The first substrate 301 may include one or more insulating or passivation layers, one or more conductive vias formed through the insulating layers, and one or more conductive layers formed over or between the insulating layers. The first substrate 301 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO₂), silicon nitride (Si₃N₄), silicon oxynitride (SiON), tantalum pentoxide (Ta₂O₅), aluminum oxide (Al₂O₃), or other material having similar insulating and structural properties. The first substrate 301 can also be a multi-layer flexible laminate, ceramic, copper clad laminate, glass, or semiconductor wafer including an active surface containing one or more transistors, diodes, and other circuit elements to implement analog circuits or digital circuits. The first substrate 301 may include one or more electrically conductive layers or redistribution layers (RDL) formed using sputtering, electrolytic plating, electroless plating, or other suitable deposition process. The conductive layers may be one or more layers of Al, Cu, Sn, Ni, Au, Ag, titanium (Ti), tungsten (W), or other suitable electrically conductive material.

As shown in FIG. 3A, the first substrate 301 includes a first surface 302 and a second surface 303 opposite to the first surface 302. Similar as shown in FIG. 1, one or more electronic components 304 and one or more conductive structures 305 are mounted on the second surface 303 of the first substrate 301, and the number of the electronic components 304 and the conductive structures 305 mounted on the second surface 303 of the first substrate 301 may be adjusted based on practical needs, which is not limited by the present application. The electronic components 304 may include one or more semiconductor components or discrete electrical devices such as resistors, capacitors, etc. Further, a protection tape 306 is attached onto the first surface 302 of the first substrate 301. In an embodiment of the present application, the protection tape 306 may be an ultraviolet tape, which can be easily removed from the first substrate 301. In particular, the UV protective tape 306 can be hardened after irradiation by UV light with a certain wavelength range. The hardened ultraviolet sensitive tape may provide effective protection for the underlaying first surface 302 and the conductive patterns formed thereon. In some embodiments, the UV protective layer 306 may include multiple layers of various UV sensitive tapes or other similar tapes. Furthermore, the UV sensitive tape that is in direct contact with the underlying first surface 302 may have high-sticky characteristics, avoiding vesicles or gaps between the UV protective tape 306 and the first surface 302. An upper UV sensitive tape layer may have greater hardness after irradiation by UV light, and therefore can be easily detached. In some other embodiments, the UV protective layer 306 may include materials such as polymer, plastic, ceramics or the like.

As illustrated in FIG. 3B, a second substrate 307 is provided, which may be a substrate strip with various similar or identical sections. The one or more packages 300 are mounted onto a first surface 308 of a second substrate 307, with the protection tapes 306 facing outward and away from the second substrate 307. In the embodiment shown in FIG. 3B, three packages 300 are mounted onto the first surface 308 of the second substrate 307, so that a semiconductor device array 320 is formed and the semiconductor device array 320 can be singulated to form multiple individual semiconductor devices, as will be described below. However, the number of packages 300 mounted onto the first surface 308 of the second substrate 307 can be adjusted based on practical needs, which is not limited by the present application. For example, in some embodiments, only one package 300 is mounted onto the first surface 308 of the second substrate 307, so a single semiconductor device rather than a semiconductor device array is formed, and no singulation process is required.

As can be seen, the conductive structures 305 of each package 300 connect the first substrate 301 of each package 300 with the second substrate 307, so that electrical signals can be transmitted between the first substrate 301 and the second substrate 307, or particularly electronic components mounted on the substrates 301 and 307. In some embodiments, the conductive structures 305 may be solder balls or other similar interconnect structures. When solder balls are used as the conductive structures 305, a reflow process may be implemented on the first and second substrates as well as components and structure mounted thereon, to reflow the solder balls and improve their attachment to t he substrates. As such, it is preferred the substrates can withstand the temperature at which the solder balls are reflowed.

Afterwards, referring to FIG. 3C, a molding material 310 is applied on the first surface 308 of the second substrate 307 and around the one or more packages 300 mounted thereon, to cover the one or more electronic components 304 and the one or more conductive structures 305 on the packages 300. As such, the one or more electronic components 304 and the one or more conductive structures 305, which may be fragile and sensitive, are protected by the molding material 310. The molding material 310 may be a high-k molding material or a low-a molding material (i.e., the material contains low content of radioactive elements such as uranium, thorium or americium, for example, 1 ppb or less), or any other suitable molding materials. In some embodiments, the molding material 310 may be formed by an injection molding process or a film-assisting molding (FAM) process. During the molding process, the protection tape 306 may be in direct contact with a mold chase for performing the molding process, and thus it can prevent the molding material from forming on the first surface 302 of the first substrate 301. Even if the molding material may lead into an interface between the protection tape 306 and the mold chase, it cannot be formed on the first surface 302 due to the existence of the protection tape 306.

Referring to FIG. 3D, after the molding material 310 is applied, the protection tape is removed from each of the one or more packages 300. In some embodiments where UV tape is used as the protection tape, before the protection tape is removed, an irradiation process by UV light may be performed to the protection tape to reduce the stickiness of the protection tape and case the removing of the protection tape. As can be seen, with the protection tape, no mold flash is formed on the first surface 302 of the first substrate 301. Even if some molding material may be formed on the protection tape during the molding process, it can be removed with the protection tape. In this way, the quality of the molding material is improved. It can be appreciated that although some sidewalls may be formed between the protection tapes of each two adjacent packages 300 before the protection tapes are removed, they may not affect the entire semiconductor devices. For example, the sidewalls may be formed at saw streets between individual semiconductor devices, which may be removed when the semiconductor devices are singulated from each other. In some other cases, an additional molding removing process or a lamination process such as a SRT process (strip router process) may be performed to remove these sidewalls.

FIGS. 3E-3H illustrate some additional processes for the semiconductor device after the protection tape is removed from each of the one or more packages. These processes may be performed to have the semiconductor device formed with a more complicated structure, and may be omitted in some embodiments. Furthermore, in some other embodiments, some alternative or additional processes may be performed on the semiconductor device.

As shown in FIG. 3E, after the protection tape is removed from each of the one or more packages 300, at least one conductive structure 311 is mounted onto the first surface 302 of the first substrate 301 of each package 300, for facilitating its connection with an external device. In some embodiments, the conductive structures 311 include solder balls and/or metal posts. For example, the conductive structure 311 can be formed by first dispensing a solder paste on the first surface 302 through a solder mask and then dispensing a flux around the solder paste on the first surface 302. In some other embodiments, the conductive structures 311 may be formed by stencil printing a solder paste onto the first surface 302.

Afterwards, referring to FIG. 3F, the semiconductor device is flipped off, and at least one electronic component 312 and/or at least one second package 313 corresponding to each of the one or more first packages 300 are mounted onto the second surface 309 of the second substrate 307. In this embodiment, one electronic component 312 and one second package 313 corresponding to each of the one or more first packages 300 are mounted onto the second surface 309 of the second substrate 307. However, the number of electronic component 312 and second package 313 corresponding to each package can be configured based on practical needs, which is not limited by the present application. For example, in some embodiments, for each package 300, no electronic component 312 but two second packages 313 are mounted onto the second surface 309 of the second substrate 307; in some other embodiments, for each package 300, three electronic components 312 but no second packages 313 are mounted onto the second surface 309 of the second substrate 307. In some embodiments, the electronic component 312 and/or the second package 313 may include semiconductor components or discrete electrical devices. In some embodiments, another molding material may be formed on the second surface 309 to encapsulate at least partially the electronic components 312 and/or the second packages 313 for encapsulation, which is not shown in FIG. 3F.

Referring to FIG. 3G, since more than one first packages 300 are mounted onto the first surface 308 of the second substrate 307, the semiconductor device array 320 with multiple units is formed. As shown, the semiconductor device array 320 can be divided into more than one semiconductor device 330 through a singulation process, and each semiconductor device 330 includes at least one first package 300. The number of first packages 300 included in each semiconductor device 300 can be configured based on practical needs, for example, one, two or three, which is not limited by the present application. In some embodiments, the singulation process may include blade sawing, laser curve cutting or SRT (strip router).

Alternatively, referring to FIG. 3H, the singulation process may be performed along the side surface of the first substrate 301 of each first package 300, so the side surface of the first substrate 301 can be exposed after the singulation process.

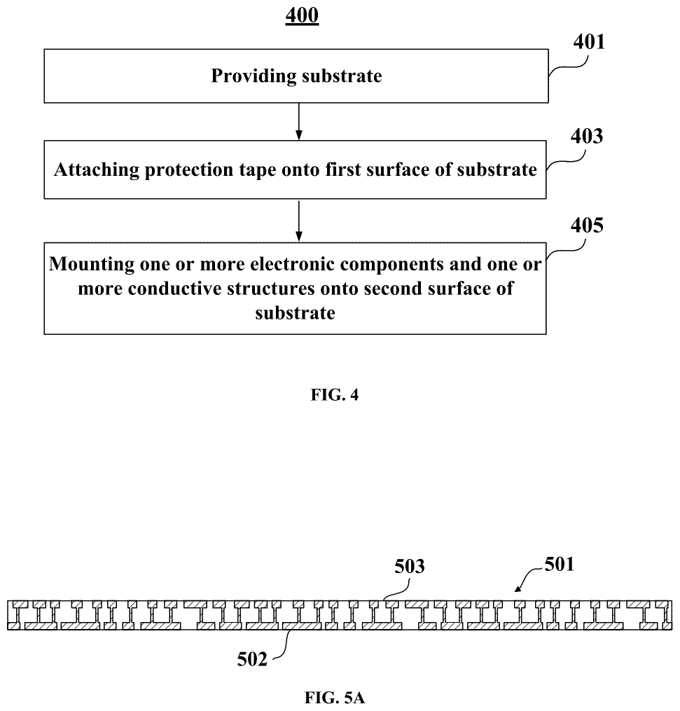

Referring to FIG. 4, a flowchart of a method 400 for making a package is illustrated according to an embodiment of the present application, for example, for making the first package 300 as illustrated in FIG. 3A. The method 400 may start with providing a substrate in block 401. In block 403, a protection tape is attached onto a first surface of the substrate. Then, in block 405, one or more electronic components and one or more conductive structures are mounted onto a second surface of the substrate.

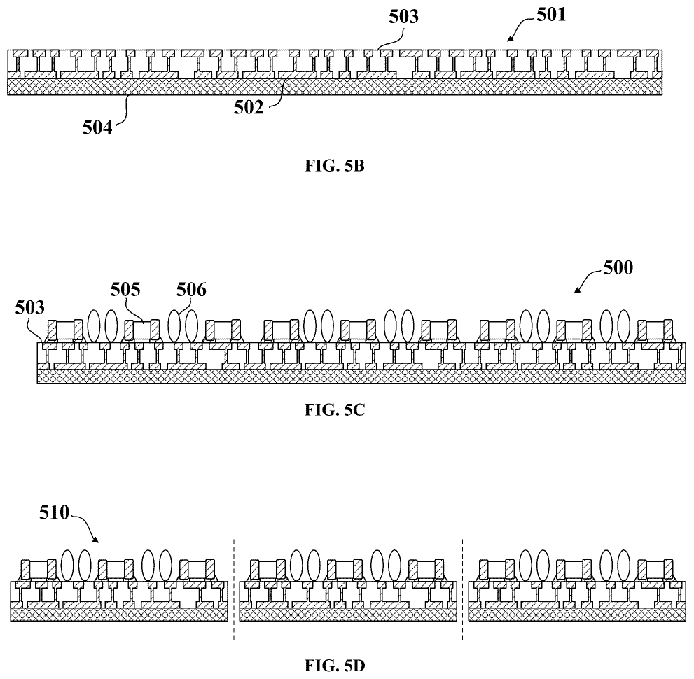

Referring to FIGS. 5A to 5D, cross-sectional views illustrating various blocks of the method for making a package are illustrated. In the following, the method will be described with reference to FIG. 4 and FIGS. 5A to 5D in more details.

As shown in FIG. 5A, a substrate 501 including a first surface 502 and a second surface 503 opposite to the first surface 502 is provided. The substrate 501 may be similar as the first substrate 301 shown in FIGS. 3A to 3H, which will not be repeated here.

Referring to FIG. 5B, a protection tape 504 is attached onto the first surface 502 of the substrate 501. The protection tape 504 may be similar as the protection tape 306 shown in FIGS. 3A to 3C, which will not be repeated here.

Afterwards, as shown in FIG. 5C, one or more electronic components 505 and one or more conductive structures 506 are mounted onto the second surface 503 of the substrate 501. The electronic components 505 and the conductive structures 506 may be respectively similar as the electronic components 304 and the conductive structures 305 as shown in FIGS. 3A to 3H, which will not be repeated here. Similarly, the number of the electronic components 505 and the conductive structures 506 mounted onto the second surface 503 of the substrate 501 can be configured based on practical needs, which is not limited by the present application. In this embodiments, more than one electronic components 505 and more than one conductive structures 506 are mounted onto the second surface 503 of the substrate 501, to form a package array 500 instead of a single package, so a singulation process may be performed on the package array 500 to divide the package array 500 into multiple packages. However, in some embodiments, less electronic components 505 and less conductive structures 506 are mounted onto the second surface 503 of the substrate 501 to only form a single package, then no singulation process is required.

Referring to FIG. 5D, the package array 500 is divided into several packages 510 (in this embodiments, three single packages 510) through a singulation process. In some embodiments, the singulation process may include blade sawing, laser curve cutting or SRT.

Then, the packages 510 formed according to the method 400 can be used as the first package 300 illustrated in FIGS. 3A to 3H, to form a semiconductor device without molding flush.

The discussion herein included numerous illustrative figures that showed various portions of a semiconductor device and a method for making the semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing one or more packages, wherein each of the one or more packages includes: a first substrate comprising a first surface and a second surface, a protection tape attached onto the first surface of the first substrate, one or more electronic components mounted on the second surface of the first substrate, and one or more conductive structures mounted on the second surface of the first substrate;
mounting the one or more packages onto a first surface of a second substrate, wherein the one or more conductive structures connect the first substrate and the second substrate;
applying a molding material to cover the one or more electronic components and the one or more conductive structures; and
removing the protection tape from each of the one or more packages.

2. The method of claim 1, wherein the one or more packages are formed by:
providing the first substrate;
attaching the protection tape onto the first surface of the first substrate; and
mounting the one or more electronic components and the one or more conductive structures onto the second surface of the first substrate.

3. The method of claim 2, wherein each of the one or more packages is divided from a package array through a singulation process.

4. The method of claim 1, further comprising mounting at least one conductive structure onto the first surface of the first substrate of each package after removing the protection tape, to connect the semiconductor device to another device.

5. The method of claim 1, wherein the one or more packages are one or more first packages, and the method further comprises mounting at least one electronic component and/or at least one second package corresponding to each of the one or more first packages onto a second surface of the second substrate.

6. The method of claim 1, wherein more than one packages are mounted onto the first surface of the second substrate to form a semiconductor device array, and the method further comprises dividing the semiconductor device array into more than one semiconductor device through a singulation process, wherein each semiconductor device includes at least one package.

7. The method of claim 1, wherein the conductive structure is mounted through a flux or a solder paste.

8. The method of claim 1, wherein the conductive structure includes a solder ball and/or a Cu post.

9. The method of claim 3, wherein the singulation process includes blade sawing, laser curve cutting or a strip router process.

10. The method of claim 4, wherein the conductive structure is mounted through a flux or a solder paste.

11. The method of claim 4, wherein the conductive structure includes a solder ball and/or a Cu post.

12. The method of claim 6, wherein the singulation process includes blade sawing, laser curve cutting or a strip router process.

13. A method for making a semiconductor device, comprising:
providing a first substrate;
attaching a protection tape onto a first surface of the first substrate;
mounting more than one electronic components and more than one conductive structures onto a second surface of the first substrate to form a package array;
dividing the package array into more than one first packages through a singulation process;
mounting the more than one first packages onto a first surface of a second substrate, wherein the conductive structures of the first packages connect the first substrate of each of the first packages with the second substrate;
applying a molding material to cover the electronic components and the conductive structures of each of the first packages;
removing the protection tape from each of the first packages;
mounting at least one conductive structure onto the first surface of the first substrate of each of the first packages;
mounting at least one electronic component and/or at least one second package corresponding to each of the first packages onto a second surface of the second substrate to form a semiconductive device array; and
dividing the semiconductor device array into more than one semiconductor devices through a singulation process, wherein each of the semiconductor devices includes at least one first package.

14. A semiconductor device formed through the method of claim 1.

15. A semiconductor device formed through the method of claim 13.
